(19) United States
(12) Patent Application Publication
(10) Pub. No.: US 2010/0166230 A1
(43) Pub. Date: Jul. 1, 2010

(54) FLAT SPEAKER STRUCTURE AND DEVICE

(75) Inventors: Kuo-Hua Tseng, Taipei County (TW); Yi-Jen Chan, Taoyuan County (TW); Chang-Ho Liou, Changhua County (TW); Ming-Daw Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/419,275

(22) Filed: Apr. 6, 2009

(30) Foreign Application Priority Data
Dec. 30, 2008 (TW) 97151418

(51) Int. Cl. H04R 1/00; H01L 31/00

(52) U.S. Cl. 381/150; 136/252

(57) ABSTRACT

A solar flat speaker structure including a flat speaker and a solar cell is provided. The flat speaker includes a chamber substrate, a diaphragm and an upper electrode; the solar cell includes a substrate, and the flat speaker is disposed on a surface of the substrate of the solar cell, so that solar power absorbed by the solar cell is converted to electricity and provided to the flat speaker. A speaker device including at least a flat speaker, a solar cell or the above solar flat speaker structure and an integrator is also provided. The integrator includes at least an audio decoder, a radio frequency receiver, a speaker amplifier, a display and a power manager. The speaker device is expanded using a folding method or a scrolling method.

### CROSS-REFERENCE TO RELATED APPLICATION

This application claims the priority benefit of Taiwan application serial no. 97151418, filed on Dec. 30, 2008. The entirety of the above-mentioned patent application is hereby incorporated by reference herein and made a part of specification.

### BACKGROUND OF THE INVENTION

1. Field of the Invention

The present invention relates to a flat speaker structure, and particularly to a solar flat speaker structure.

2. Description of Related Art

As oil prices rise continuously in recent years, many countries are vigorously developing energy conserving technologies and products, in which the most attention is paid to applications of solar energy. The energy conserving technologies are also a main trend in development of consumer products in the future.

Two most direct senses of human beings are vision and hearing, so scientists have been devoted to developing related devices or systems for a long time. Relating to hearing systems, current speakers may be generally classified into moving-coil speakers, piezoelectric speakers and electrostatic speakers according to driving mechanisms. The moving-coil speakers are currently the main type which is the most widely used, having mature technology and controlling the whole market. However, due to inherent characteristics of structure thereof, they are difficult to be flattened. The piezoelectric speakers utilize piezoelectric effects of piezoelectric materials, which are characteristic of deformation when an electrical field is applied to the piezoelectric material, to drive a diaphragm to generate sound. Such speaker structures may be flattened and miniaturized, but the piezoelectric materials need to be sintered at high temperatures. The electrostatic speakers are the type mainly used in high-end headphones and speaker products in the market. A functioning mechanism of a conventional electrostatic speaker is using two electrodes having a plurality of openings to hold a diaphragm, so as to form a capacitor, and driving the diaphragm to generate sound by supplying the diaphragm with a direct current bias, by supplying the two electrodes with alternating current voltages of audio frequencies and by using electrostatic forces generated by positive and negative electric fields.

### SUMMARY OF THE INVENTION

Embodiments disclosed herein may provide a solar flat speaker structure, which includes a flat speaker and a solar cell, wherein the flat speaker includes a chamber substrate, a diaphragm and an upper electrode. The solar cell includes a substrate, and the flat speaker is disposed on a surface of the substrate.

Embodiments disclosed herein may provide a speaker device, which includes at least a flat speaker and a solar cell or the above solar flat speaker structure and an integrator. The integrator includes an audio decoder, a radio frequency receiver, a speaker amplifier, a display and a power manager.

In order to the make aforementioned and other objects, features and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view showing a solar flat speaker structure according to an embodiment of the present invention.

FIG. 1B is a top view showing a solar flat speaker structure according to an embodiment of the present invention.

FIG. 1C is a more detailed schematic cross-sectional view showing a solar flat speaker structure according to an embodiment of the present invention.

FIG. 1D is a schematic cross-sectional view showing a solar flat speaker structure according to an embodiment of the present invention.

FIG. 2A is a schematic cross-sectional view showing a solar flat speaker structure according to an embodiment of the present invention.

FIG. 2B is a top view showing a solar flat speaker structure according to an embodiment of the present invention.

FIG. 2C is a more detailed schematic cross-sectional view showing a solar flat speaker structure according to an embodiment of the present invention.

FIG. 3A is a schematic cross-sectional view showing a solar flat speaker structure according to an embodiment of the present invention.

FIG. 3B is a top view and a bottom view showing a solar flat speaker structure according to an embodiment of the present invention.

FIG. 3C is a more detailed schematic cross-sectional view showing a solar flat speaker structure according to an embodiment of the present invention.

FIG. 4A is a schematic cross-sectional view showing a solar flat speaker structure according to an embodiment of the present invention.

FIG. 4B is a top view and a bottom view showing a solar flat speaker structure according to an embodiment of the present invention.

FIG. 4C is a more detailed schematic cross-sectional view showing a solar flat speaker structure according to an embodiment of the present invention.

FIG. 5 is a schematic view showing a speaker device according to an embodiment of the present invention.

FIG. 6 is a schematic view showing a speaker device according to an embodiment of the present invention.

### DESCRIPTION OF EMBODIMENTS

A solar flat speaker structure provided according to an embodiment of the present invention includes a combination of a flat speaker and a solar cell. The flat speaker may adopt a Flexpeaker® structure provided by Applicants and includes a chamber substrate, a diaphragm and an upper electrode. The solar cell may adopt a flexible thin solar cell structure or other solar cell structures, for example a solar cell structure including monocrystalline silicon, amorphous silicon or polycrystalline silicon or materials as such. The flat speaker is disposed on a surface of the substrate of the solar cell structure. Since electricity utilization of the flat speaker is five to ten times more efficient than that of common moving-coil speakers on the market, the flat speaker may use common solar cells for driving electricity, thereby greatly enhancing convenience of usage.

A structure according to an embodiment of the present invention adopts, for example, the Flexpeaker® and the flexible thin solar cell structure, so as to become a so-called solar Flexpeaker®. Under international A2 standards and requirements of standard sound 85 db at 1 meter (db@1 m), a power measured for an area of 594 mm×420 mm is 0.031 to 0.04 Watt. When adopting the flexible thin solar cell structure, if a conversion efficiency achieves 28.5%, electricity power output per gram achieves 2.6 Watts. Therefore, in a structure of combining the solar cell and the flat speaker, the solar cell provides sufficient electricity to the flat speaker. Besides having characteristics of being light, thin and flexible, the flat speaker structure provided according to an embodiment of the present invention may be manufactured in large areas and large quantities using roll-to-roll manufacturing. By combining the low power consuming and high electro-audio efficiency flat speaker and using the solar cell as a main or an auxiliary power source of the flat speaker, convenience in usage is greatly enhanced.

The solar flat speaker structure according to an embodiment of the present invention converts solar energy to the main or the auxiliary power source for the flat speaker through an integrating design of processes and structures, thereby effectively lowering dependence on external power (for example urban electricity and batteries) and implementing energy conservation and cutting carbon emission, so that applications in products is more widespread and complying more to new worldwide trends of environmental protection and energy conservation in the future.

### First Embodiment

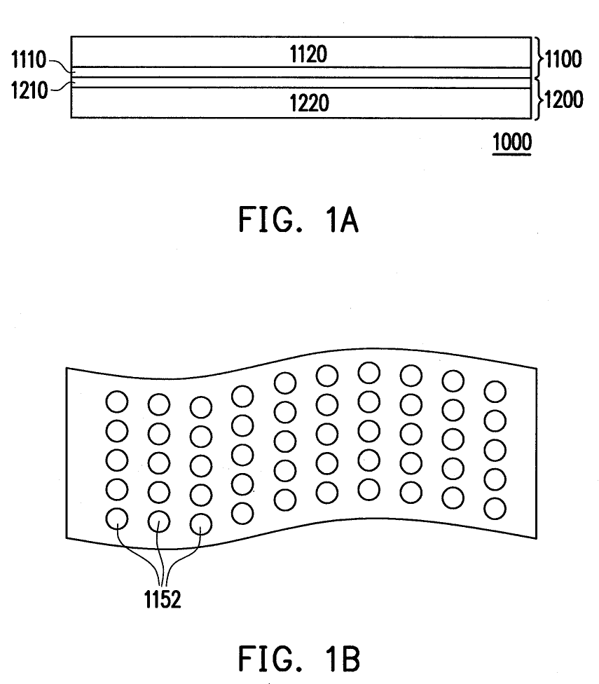

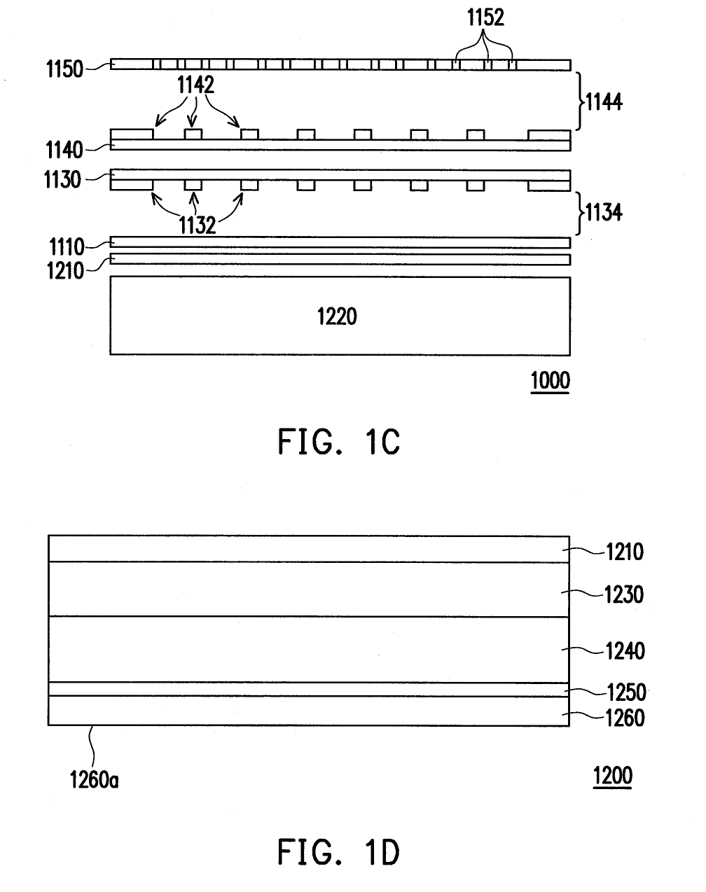

Please refer to FIGS. 1A and 1B, which respectively are a schematic cross-sectional view and a top view of a solar flat speaker structure according to an embodiment of the present invention. A solar flat speaker structure 1000 includes a flat speaker 1100 and a solar cell 1200. The flat speaker 1100 includes a chamber substrate 1110. The solar cell 1200 includes a substrate 1210, and the chamber substrate 1110 is disposed on a surface of the substrate 1210. 1120 and 1220 respectively represent other structures of the flat speaker 1100 and the solar cell 1200 and are illustrated in detail in FIGS. 1C and 1D.

Please refer to FIG. 1C, which is a more detailed schematic cross-sectional view showing a solar flat speaker structure according to an embodiment of the present invention. The flat speaker 1100 further includes a diaphragm electrode 1130, a diaphragm 1140 and an upper electrode 1150, wherein a plurality of chamber supporters 1132 are disposed on a surface of the diaphragm electrode 1130 near the chamber substrate 1110, a plurality of supporters 1142 are disposed on a surface of the diaphragm 1140 near the upper electrode 1150, and the upper electrode 1150 includes a plurality of openings 1152. The diaphragm electrode 1130 and the chamber substrate 1110 form a chamber 1134, and the diaphragm 1140 and the upper electrode 1150 form another chamber 1144. The chamber supporters 1132 and the supporters 1142 are respectively disposed in spaces formed by the chamber 1134 and the chamber 1144, which are used as vibrating spaces for the diaphragm 1140 to generate sound. A surface of the chamber substrate 1110 distant from the diaphragm electrode 1130 is adjacent to the solar cell 1200, and is used to convert solar energy received by the substrate 1210 into electricity.

The upper electrode 1150 may include conductive material, or may be formed by plating a metallic thin film on a layer of a flexible material, for example paper or an extremely thin nonconductive material.

When the upper electrode 1150 is formed by plating the metallic thin film on the layer of the nonconductive material, the nonconductive material may be plastic, rubber, paper, nonconductive cloth (cotton fibers or polymeric fibers), and the metallic thin film may be pure metals such as aluminum, gold, silver, copper, alloys thereof, nickel/gold bimetals, indium tin oxide (ITO), indium zinc oxide (IZO), any combination of above or a polymeric conductive material poly(3,4-ethylenedioxythiophene) (PEDOT).

When the upper electrode 1150 includes the conductive material, the conductive material may be metal (iron, copper, aluminum or alloys thereof) or conductive cloth (metallic fibers, metal oxide fibers, carbon fibers or graphite fibers).

A dielectric material may be chosen as a material of the diaphragm 1140. The dielectric material retains static charges for a long period of time after an electrochemical process, and electron-retaining effects are generated in the dielectric material after being charged. The diaphragm 1140 may include a single layer or a plurality of layers of dielectric materials, and the dielectric materials may be fluorinated ethylenepropylene (FEP), polytetrafluoethylene (PTFE), polyvinylidene fluride (PVDF), fluorine polymers partially including fluorine or other suitable materials. Insides of the dielectric materials include pores having micrometer or nanometer diameters. Since the dielectric material of the diaphragm 1140 is electrochemically processed, the static charges and piezoelectric properties are retained for a long period of time. The pores having the micrometer or nanometer diameters increase transmittance and the piezoelectric properties, so that after corona charging, dipolar charges are generated in the dielectric material, thereby generating the electron-retaining effects.

In order not to affect effects of tension and vibration of the diaphragm 1140, the above diaphragm electrode 1130 may be an extremely thin metallic thin film electrode. Here the phrase “extremely thin” is defined between 0.2 micrometer and 0.8 millimeter, and preferably between 0.2 micrometer and 0.4 micrometer. 0.3 micrometer may be chosen.

The diaphragm 1140 drives the diaphragm electrode 1130 to vibrate together according to the filled electrical charges and a voltage of input audio signals, and generates sound output by compressing nearby air.

A side or two sides surrounding the solar flat speaker structure 1000 according to the present embodiment may be covered with a ventilating waterproof thin film (not shown), wherein a material of the thin film is, for example, a GORE-TEX thin film of elastic polytetrafluoethylene (ePTFE). The thin film prevents effects of moisture and prevents the electrical charges in the diaphragm 1140 from leaking and affecting the electron-retaining effects.

The chamber 1134 and the chamber 1144 are places where resonating sound fields are generated. Disposition methods and heights of both the chamber supporters 1132 and the supporters 1142 may be adjusted according to requirements of design, and a number of the chamber supporters 1132 may be equal to, less than or greater than a number of the supporters 1142. The chamber supporters 1132 and the supporters 1142 may be respectively disposed on the chamber substrate 1110 and the upper electrode 1150. In addition, the disposition methods, heights and shapes of the chamber supporters 1132 and the supporters 1142 are adjusted according to concerns of audio frequency design.

Next, please refer to FIG. 1D, which is a schematic cross-sectional view showing a solar flat speaker structure according to an embodiment of the present invention. The solar cell 1200 is, for example, a common flexible solar cell structure or other common photo-electric conversion devices. The following uses the common solar cell as an example for illustration, but the present invention is not limited thereto. The solar cell 1200 is manufactured by semiconductor processes and generates electricity using electrical potential differences. A mechanism for generating electricity is letting sunlight shine on a surface 1260a of the solar cell 1200, generating electrons and electron holes through a P-type semiconductor layer 1230 and an N-type semiconductor layer 1240 and forming a voltage drop between the substrate 1210 and a lower electrode 1260 by separating the electrons and the electron holes at, the same time, so as to form an electrical current. An anti-reflective layer 1250 is further disposed on the solar cell 1200 to increase an efficiency of the sunlight being absorbed.

In brief, the solar cell 1200 directly converts sunlight to output of electrical energy by absorbing the sunlight having wavelengths between 0.2 micrometer and 0.4 micrometer.

### Second Embodiment

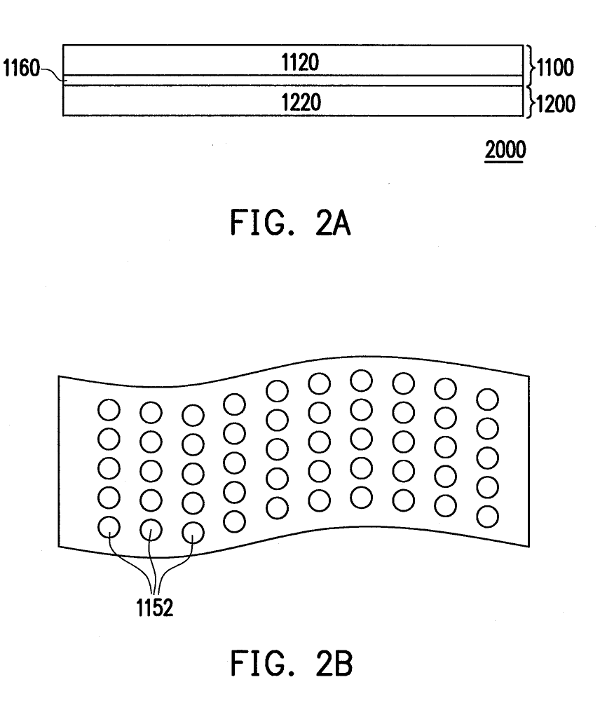

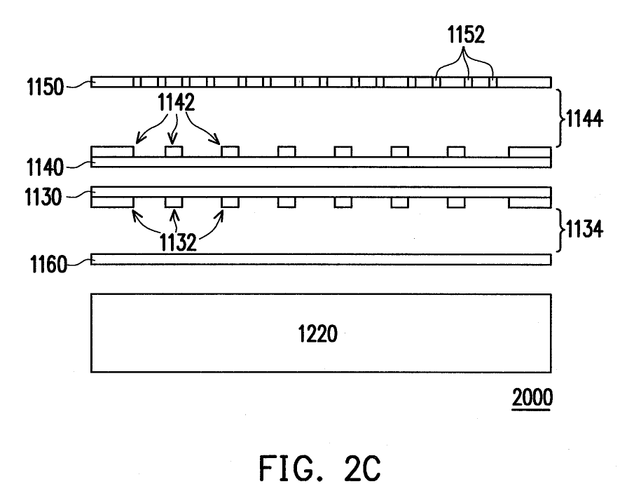

Please refer to FIGS. 2A and 2B, which respectively are a schematic cross-sectional view and a top view of a solar flat speaker structure according to an embodiment of the present invention.

Referring to FIG. 2A, a solar flat speaker structure 2000 includes the flat speaker 1100 and the solar cell 1200. The flat speaker 1100 and the solar cell 1200 share a substrate, meaning that the chamber substrate of the flat speaker 1100 and the substrate of the solar cell 1200 are combined into a solar cell chamber substrate 1160.

Please refer to FIG. 2C, which is a more detailed schematic cross-sectional view showing a solar flat speaker structure according to an embodiment of the present invention. The flat speaker 1100 further includes the diaphragm electrode 1130, the diaphragm 1140 and the upper electrode 1150, wherein the plurality of chamber supporters 1132 are disposed on the surface of the diaphragm electrode 1130 near the solar cell chamber substrate 1160, the plurality of supporters 1142 are disposed on the surface of the diaphragm 1140 near the upper electrode 1150, and the upper electrode 1150 includes the plurality of openings 1152. The diaphragm electrode 1130 and the solar cell chamber substrate 1160 form the chamber 1134, and the diaphragm 1140 and the upper electrode 1150 form the other chamber 1144. The chamber supporters 1132 and the supporters 1142 are respectively disposed in the spaces formed by the chamber 1134 and the chamber 1144, which are used as the vibrating spaces for the diaphragm 1140 to generate sound.

The present embodiment is approximately identical to the first embodiment, and same or similar reference numerals represent the same or similar elements. The solar cell 1200 according to the present embodiment is approximately identical to that according to the first embodiment, so that repeated description is omitted.

A difference between the solar flat speaker structure 2000 according to the present embodiment and that according to the first embodiment is that, according to the present embodiment, the chamber substrate 1110 and the substrate 1210 according to the first embodiment is combined into the solar cell chamber substrate 1160, which has functions of both the chamber substrate 1110 and the substrate 1210.

### Third Embodiment

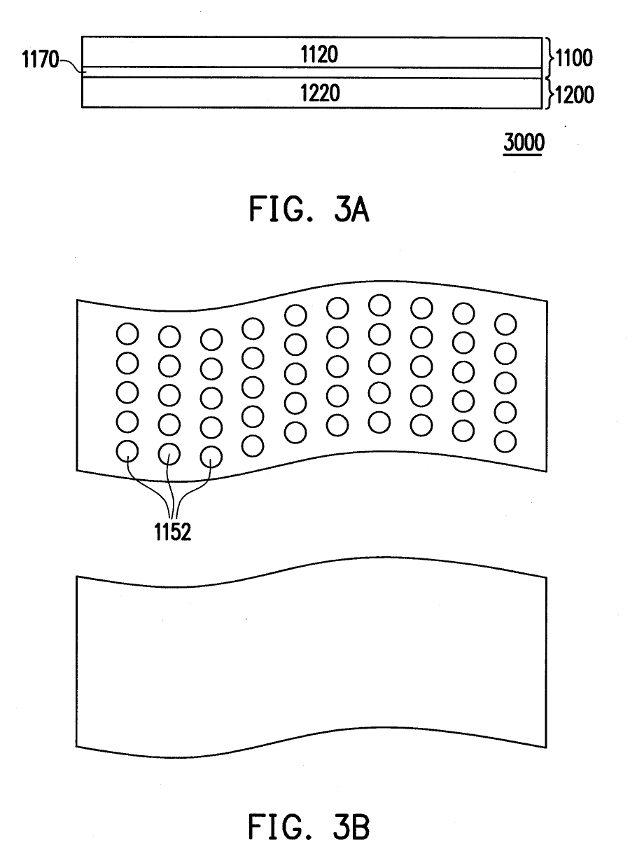

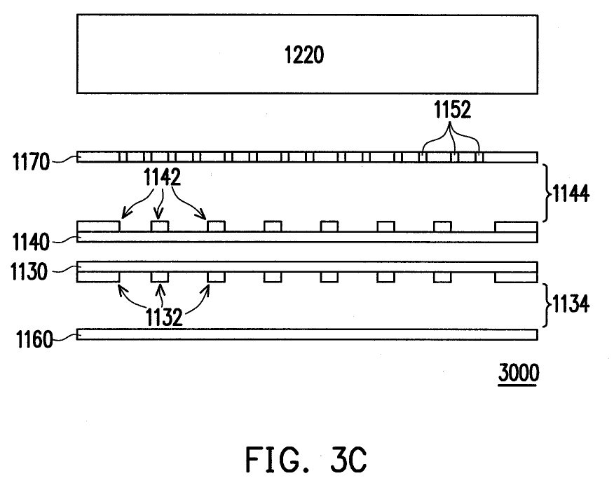

Please refer to FIGS. 3A and 3B, which respectively are a top view and a bottom view of a solar flat speaker structure according to an embodiment of the present invention. A solar flat speaker structure 3000 according to the present embodiment includes the flat speaker 1100 and the solar cell 1200, and a solar cell substrate upper electrode 1170 is disposed between the flat speaker 1100 and the solar cell 1200. The solar cell substrate upper electrode 1170 includes both functions of the upper electrode of the flat speaker 1100 and functions of the substrate of the solar cell 1200. Please refer to FIG. 3C, which is a more detailed schematic cross-sectional view showing a solar flat speaker structure according to an embodiment of the present invention.

The flat speaker 1100 further includes the diaphragm electrode 1130, the diaphragm 1140 and the upper electrode 1150, wherein the plurality of chamber supporters 1132 are disposed on the surface of the diaphragm electrode 1130 near the solar cell chamber substrate 1160, the plurality of supporters 1142 are disposed on the surface of the diaphragm 1140 near the upper electrode 1150, and the upper electrode 1150 includes the plurality of openings 1152. The diaphragm electrode 1130 and the solar cell chamber substrate 1160 form the chamber 1134, and the diaphragm 1140 and the upper electrode 1150 form the other chamber 1144. The chamber supporters 1132 and the supporters 1142 are respectively disposed in the spaces formed by the chamber 1134 and the chamber 1144, which are used as the vibrating spaces for the diaphragm 1140 to generate sound.

The present embodiment is approximately identical to the second embodiment, and same or similar reference numerals represent the same or similar elements. The solar cell 1200 according to the present embodiment is approximately identical to that according to the first embodiment, so that repeated description is omitted.

A difference between the solar flat speaker structure 3000 according to the present embodiment and that according to the second embodiment is that the upper electrode having the plurality of openings according to the second embodiment is replaced by the solar cell substrate upper electrode 1170 according to the present embodiment. The solar cell substrate upper electrode 1170 includes both functions of the upper electrode of the flat speaker 1100 and functions of the substrate of the solar cell 1200. Hence, according to a disposition method of the present embodiment, both two surfaces of the solar flat speaker structure 3000, referring to a top and a bottom of FIG. 3B, absorb the sunlight.

### Fourth Embodiment

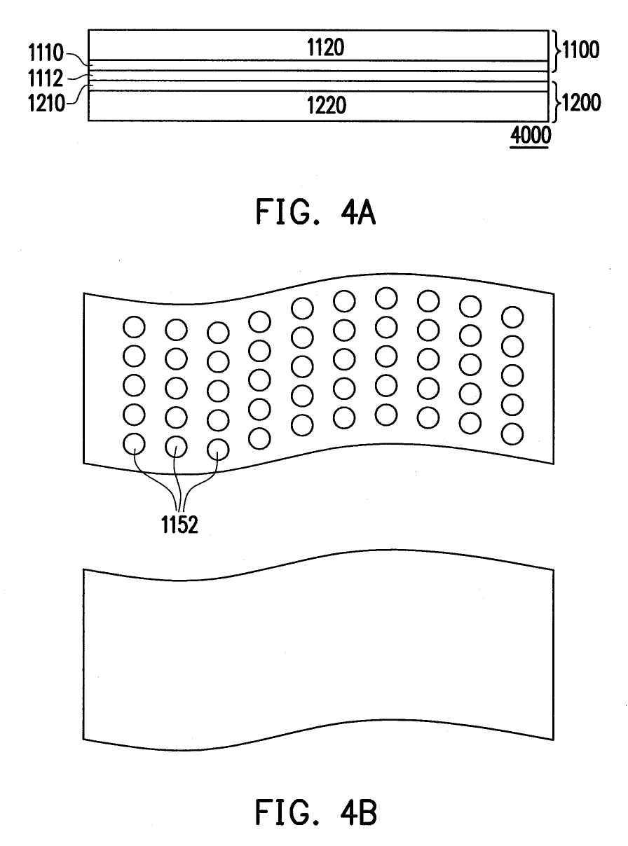

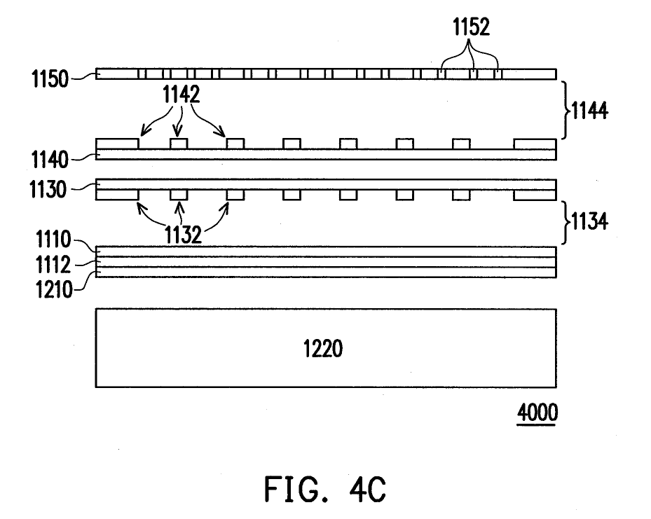

Please refer to FIGS. 4A and 4B, which respectively are a top view and a bottom view of a solar flat speaker structure according to an embodiment of the present invention.

Please refer to FIG. 4C, which is a more detailed schematic cross-sectional view showing a solar flat speaker structure according to an embodiment of the present invention.

The present embodiment is approximately identical to the first embodiment, and same or similar reference numerals represent the same or similar elements. The solar cell 1200 according to the present embodiment is approximately identical to that according to the first embodiment, so that repeated description is omitted.

A difference between a solar flat speaker structure 4000 according to the present embodiment and that according to the first embodiment is that the chamber substrate 1100 and the substrate 1120 according to the first embodiment are adhered together using an adherence material layer 1112. The adherence material layer 1112 may have heat insulating functions, so as to insulate effects of the sunlight on the flat speaker. Compared with the second embodiment, although producing the solar flat speaker structure 4000 according to the present embodiment requires two additional procedures, materials may be readily obtained, thereby being beneficial to expediting certification of products.

### Fifth Embodiment

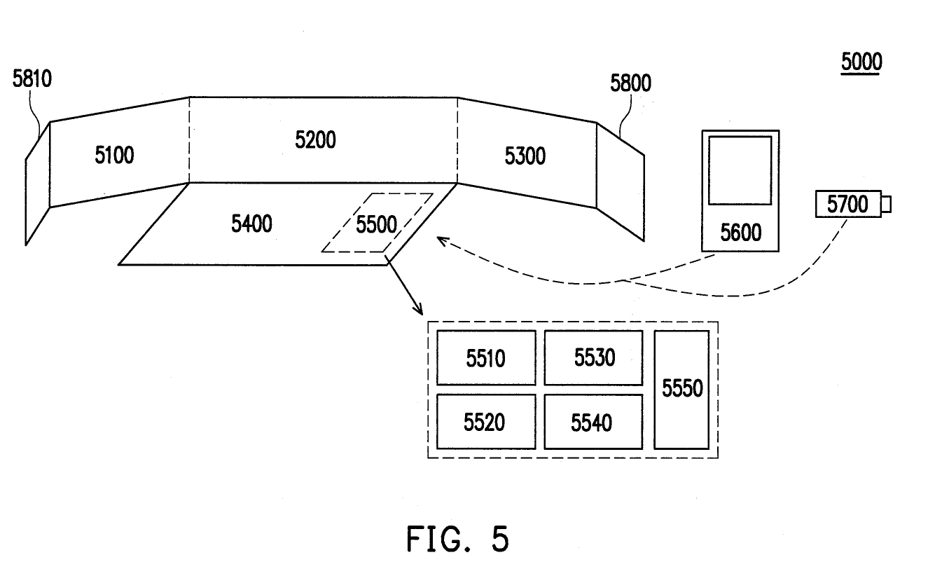

Please refer to FIG. 5, which is a schematic view showing a speaker device according to an embodiment of the present invention.

A speaker device 5000 includes at least a flat speaker and a solar cell or the above solar flat speaker structure and an integrator. According to the present embodiment, there are four solar flat speaker structures, including 5100, 5200, 5300 and 5400. The solar flat speaker structures may be expanded using a folding or sliding method. Each of the solar flat speaker structures is, for example, the solar flat speaker structure according to the above embodiments, so that each of the solar flat speaker structures absorbs solar energy.

The speaker device 5000 further includes an integrator 5500, which may include an audio decoder 5510, a radio frequency receiver 5520, a speaker amplifier 5530, a display 5540 and a power manager 5550. Moreover, the integrator 5500 obtains audio signals from a handheld device 5600, for example a personal digital assistant (PDA), a wireless phone or an audio player, through wired transmission or wireless transmission. A data storage device 5700 is, for example, a computer, a universal serial bus (USB) storage device or a microphone.

During usage, the speaker device 5000 may be expanded for charging, and the audio signals are transmitted to the integrator 5500 through the wired transmission or the wireless transmission and then played after being processed by the integrator. An exterior of the speaker device 5000 may be designed to any shapes according to usage, thereby being convenient for display and carriage.

In addition, standing boards 5800 and 5810 may be disposed on two sides of the solar flat speaker structures 5100, 5200 and 5300, so as to adjust quality of sound generated by the solar flat speaker structures, for example avoiding interference between each other or enhancing adjustment of directions.

### Sixth Embodiment

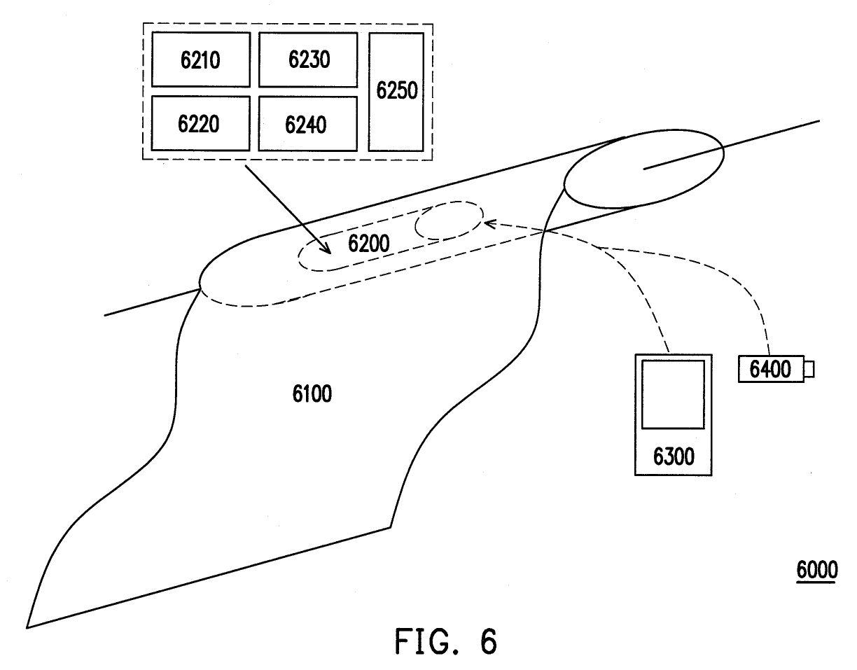

Please refer to FIG. 6, which is a schematic view showing a speaker device according to an embodiment of the present invention.

A speaker device 6000 includes at least a flat speaker and a solar cell or the above solar flat speaker structure and an integrator. Each of the solar flat speaker structures may be expanded using a scrolling method. Each of the solar flat speaker structures is, for example, the solar flat speaker structure according to the above embodiments.

The speaker device 6000 further includes an integrator 6200, which may include an audio decoder 6210, a radio frequency receiver 6220, a speaker amplifier 6230, a display 6240 and a power manager 6250. In addition, the integrator 6200 obtains audio signals from a handheld device 6300, for example a PDA, a wireless phone or an audio player, through wired transmission or wireless transmission. A data storage device 6400 is, for example, a computer, a USB storage device or a microphone.

During usage, the speaker device 6000 may be expanded for charging, and the audio signals are transmitted to the integrator 6200 through the wired transmission or the wireless transmission and then played after being processed by the integrator 6200. An exterior of the speaker device 6000 may be designed to any shapes according to usage, thereby being convenient for display and carriage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar flat speaker structure, comprising a flat speaker and a solar cell, wherein the flat speaker comprises a chamber substrate, a diaphragm and an upper electrode, the solar cell comprises a substrate, and the flat speaker is disposed on a surface of the substrate.

2. The solar flat speaker structure of claim 1, wherein the chamber substrate and the substrate are replaced by a solar cell chamber substrate.

3. The solar flat speaker structure of claim 2, wherein the upper electrode is replaced by a solar cell substrate upper electrode.

4. The solar flat speaker structure of claim 1, wherein the flat speaker and the solar cell are adhered together using an adherence material layer.

5. The solar flat speaker structure of claim 4, wherein the adherence material layer is a double-sided tape or a colloid substance having adhesiveness.

6. The solar flat speaker structure of claim 1, being flexible or non-flexible.

7. The solar flat speaker of claim 1, wherein the solar cell is one of a monocrystalline silicon solar cell, a polycrystalline silicon solar cell or an amorphous silicon solar cell.

8. A speaker device, comprising at least a solar flat speaker structure and an integrator, wherein the solar flat speaker structure comprises a flat speaker and a solar cell, the flat speaker comprises a chamber substrate, a diaphragm and an upper electrode, the solar cell comprises a substrate and the flat speaker is disposed on a surface of the substrate of the solar cell, the integrator comprising an audio decoder, a radio frequency receiver, a speaker amplifier, a display and a power manager.

9. The speaker device of claim 8, wherein the integrator obtains audio signals from one of a handheld device, a data storage device or a microphone through wired transmission or wireless transmission.

10. The speaker device of claim 8, wherein a plurality of solar flat speaker structures are expanded using a folding method, a sliding method or a scrolling method.

11. The speaker structure of claim 8, wherein when a plurality of solar flat speaker structures are expanded using a folding method, the solar flat speaker structures further comprising a pair of standing boards disposed on two sides of the solar flat speaker structures.
